(19) United States
(12) Patent Application Publication
(10) Pub. No.: US 2026/0194431 A1
(43) Pub. Date: Jul. 9, 2026

(54) Method for inspecting a silicon carbide wafer

(71) Applicant: LEAP Semiconductor Corp., Taoyuan City (TW)

(72) Inventors: Wen-Chung LI, Taoyuan City (TW); Kai-Chi Hsiao, Taoyuan City (TW)

(21) Appl. No.: 19/185,403

(22) Filed: Apr. 22, 2025

(30) Foreign Application Priority Data
Jan. 9, 2025 (TW) 114100866

(51) Int. Cl. G01N 3/28; H01L 21/306

(52) U.S. Cl. CPC G01N 3/28; H10P 50/642

(57) ABSTRACT

The present invention relates to a method for inspecting a silicon carbide wafer. This method discloses the structural composition of various layers within the silicon carbide wafer, comprising the subsurface damaged layer and the undamaged layer, by analyzing material information in a vertical cross-section. The invention could enable to classify wafer for facilitating further applications.

### BACKGROUND OF THE INVENTION

### 1. Field of the Invention

The present invention relates to a method for inspecting a wafer, more particularly a method for inspecting a damage region and an elastic deformation region of a silicon carbide wafer.

### 2. Description of the Prior Art

Currently, silicon carbide wafers are cut from silicon carbide ingots by using diamond wire cutting technology or laser cutting technology to achieve the required thickness. However, regardless of whether diamond wire cutting technology or laser cutting technology is used during the cutting process, there is a high likelihood that the silicon carbide wafer will experience mechanical stress and damage, which are induced in the silicon carbide wafer. The mechanical stress generated during cutting or the energy applied during laser thermal ablation can cause surface damage and subsurface damage to the silicon carbide wafer, which manifests as a subsurface damage layer.

Since the yield strength of silicon carbide material at room temperature is as high as several hundred megapascals (approximately 250 MPa), extremely high internal stress may exist in the elastic deformation region without being visibly manifested. Therefore, solely relying on the microcracks observed in the surface and shallow structures of the silicon carbide wafer, which reflect the brittle characteristics, to evaluate whether the wafer is suitable for subsequent device fabrication may lead to misjudgment. This could ultimately result in a lower yield in the fabrication process of silicon carbide devices.

Normally, at room temperature, the vertical structure of silicon carbide wafer from the surface to the interior of the material can be categorized into a subsurface damage layer and an undamage layer. The subsurface damage layer can be further divided into the following sequential regions:
(a) shattered/amorphous region,
(b) damage region, and
(c) elastic deformation region.

The damage and mechanical stress in a silicon carbide wafer generally manifest within the subsurface damage layer in the following:
(a) shattered/amorphous region of the silicon carbide wafer manifests as surface roughness.
(b) damage region of the silicon carbide wafer is manifested in the form of microcracks.
Furthermore, (c) elastic deformation region at room temperature, due to the extremely high yield strength of silicon carbide, no observable microscopic structural changes caused by stress can be detected. Instead, this stress is stored in the elastic deformation region.

On the other hand, the undamage layer retains the original material characteristics of silicon carbide.

In terms of current material surface analysis technology, damage region can be inspected by destructive analysis method, such as cross-sectional electron microscopy (EM), which is required for observation. Regarding the (c) elastic deformation region in silicon carbide, although X-ray analysis can be utilized as a tool for assessing internal stress conditions, the absence of distinct microstructural features makes it challenging to directly characterize this region. As a result, there is currently no established technique in the field to reveal the thickness information of the (c) elastic deformation region formed during the fabrication process of a silicon carbide wafer.

The importance of (c) elastic deformation region lies in its impact on subsequent device fabrication.—Taking typical epitaxial growth or ion implantation processes as examples, the processing temperature typically exceeds 1,600° C. During these fabrication processes, the temperature surpasses the ductile-to-brittle transition temperature (DBTT) of silicon carbide. At this point, the high internal stress within the silicon carbide material exceeds the critical yield strength at the given processing temperature.

Consequently, the high internal stress in the silicon carbide wafer. particularly in the elastic deformation region, tends to be released through the formation of dislocations or defects.

The presence of the high internal stress in the elastic deformation region makes a challenge to intuitively evaluate and control the suitability of silicon carbide wafers in subsequent fabrication processes using existing technologies. This highlights the need for industry to develop effective testing methods to improve process efficiency and product quality.

### SUMMARY OF THE INVENTION

The present invention discloses a method for inspecting a silicon carbide wafer, which involves revealing material information of each layer structure in the vertical cross-section of the silicon carbide wafer. These layers includes the “damage region”, “elastic deformation region” and “undamage layer” as defined in this invention. This method facilitates the assessment of the wafer's reliability for subsequent applications.

The present invention provides a method for inspecting a silicon carbide wafer. The first embodiment of the invention is disclosed as the following steps:
Firstly, a single-crystal silicon carbide wafer with a specific surface area is selected as the test wafer, which is prepared at room temperature. Next, a standard for brittleness analysis is established, and performed, wherein the brittle characteristics at room temperature are identified by the presence of microcracks.
Then, the test wafer is affixed to the inclined plane of a wedge-shaped metal mold by using a wax-coating method. Subsequently, chemical etching is performed with a mixed solution of molten inorganic alkali and carbonate to reveal the wafer's brittle characteristics.
Finally, the test wafer is taken to rinse, and the inclined plane of the test wafer is examined. The length (L1) of microcracks on the inclined surface is then measured.

The present invention provides a method for detecting a silicon carbide wafer. The second embodiment of the invention is disclosed as the following steps:
Firstly, a single-crystal silicon carbide wafer with a specific surface area is selected as the test wafer. The test wafer then undergoes a heat treatment process in a high-temperature furnace to establish a standard for ductility analysis, allowing differentiation of the elastic deformation layer with excessive internal stress, referred to as the “high-internal-stress elastic deformation layer”.
Then, the test wafer is affixed to the inclined surface of a wedge-shaped metal mold by using a wax-coating method. Subsequently, chemical etching is performed by using molten inorganic alkali to reveal the wafer's ductility characteristics.
Finally, the test wafer is taken to rinse, and the inclined plane of the test wafer is examined. The distance (L2) between the dislocation etching pits and the polishing interface on the inclined plane of the test wafer is measured.

One of the advantages of the invention for the wafer is to discloses the inside information of vertical structure for the silicon carbide wafer, including the “damage layer”, “high-stress elastic deformation layer”, and “undamage layer”. Thus, the invention assists to classify the wafers for further application.

One of the advantages of the invention for the wafer is to obtains the inside thickness of each layer structure of the silicon carbide wafer, including the “damage layer”, “high-stress elastic deformation layer”, and “undamage layer”.

One of the advantages of the invention for the wafer is to completely remove the “damage layer” and the “high-stress elastic deformation layer” for device fabrication at the early stage or for using as a wafer seed.

One of the advantages of the invention for the wafer is to keep the internal stress below the critical yield strength throughout the fabrication process, thereby prevents defects.

### BRIEF DESCRIPTION OF THE DRAWINGS

The foregoing aspects and advantages of this invention will become more apparent from the following detailed description, in conjunction with the accompanying drawings, wherein:

FIG. 1A illustrates a method for inspecting a damage layer of a silicon carbide wafer according to the present invention.

FIG. 1B illustrates a method for inspecting a high-stress elastic deformation layer of a silicon carbide wafer according to the present invention.

FIG. 2(a) is a schematic diagram showing a silicon carbide wafer affixed to a wedge-shaped metal mold after cutting.

FIG. 2(b) is a schematic diagram showing the microcracks or dislocations after polishing or etching for the silicon carbide wafer.

FIG. 2(c) is an optical microscope image of the silicon carbide wafer before etching.

FIG. 2(d) is an optical microscope image with the microcracks of the silicon carbide wafer after etching.

FIG. 2(e) is an optical microscope image showing the etching pits of dislocation and the interface of polishing/grinding surface; the distance of the farthest etching pits from the interface can be defined as the “high-stress elastic deformation layer”.

FIG. 2(f) illustrates the vertical structure of the silicon carbide wafer.

### DESCRIPTION OF THE PREFERRED EMBODIMENT

The present invention provides a method for inspecting a silicon carbide wafer, which discloses the inside information of the vertical structure, including the “damage layer”, “high-stress elastic deformation layer”, and “undamage layer”. Thus, the invention assists to classify the wafers for further application.

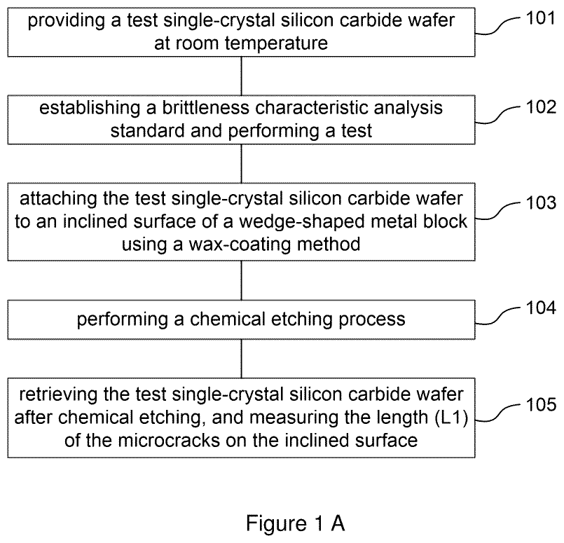

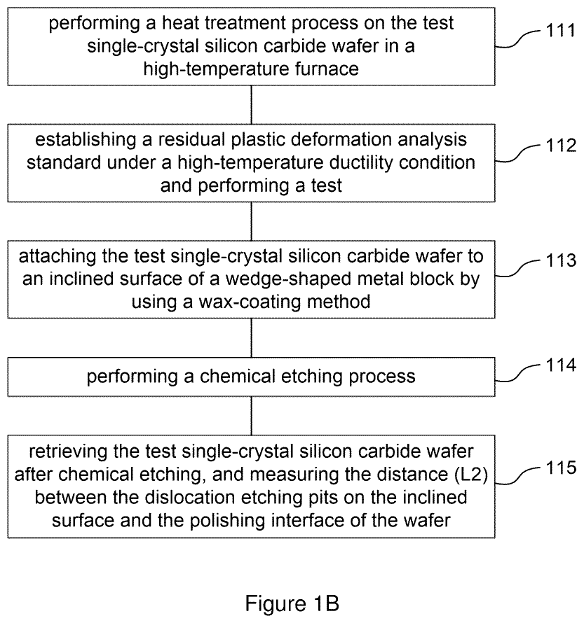

FIG. 1A illustrates a method for inspecting a silicon carbide wafer according to the first embodiment of the invention. In this embodiment, a single-crystal silicon carbide wafer with an area ranging from 100 mm² to 400 mm² is selected as the test wafer.

As shown in Step 101 of FIG. 1A, a silicon carbide single-crystal wafer is prepared for the test at room temperature.

As shown in Step 102 of FIG. 1A, a standard characteristic for brittleness is established, which is identified by the presence of microcracks at room temperature.

As shown in Step 103 of FIG. 1A, the single-crystal silicon carbide test wafer is affixed to the inclined plane of a wedge-shaped metal mold by using a wax-coating method, wherein the inclination angle ranges from 1° to 20°. A silicon wafer or another silicon carbide wafer of the same surface area is selected and bonded to the single-crystal silicon carbide test wafer by using the same wax-coating method to protect the test wafer during the test process.

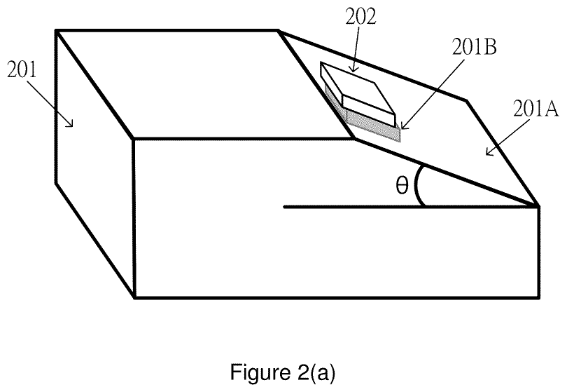

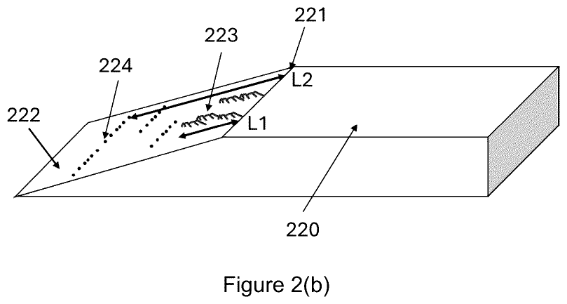

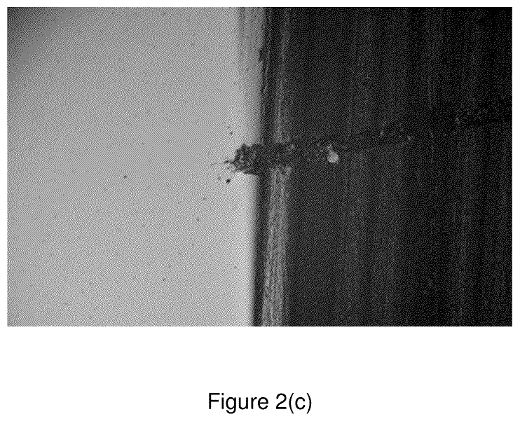

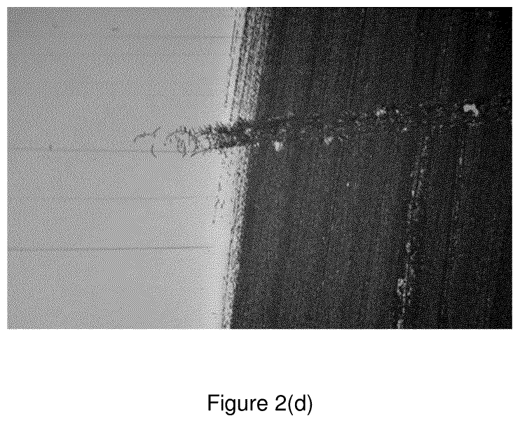

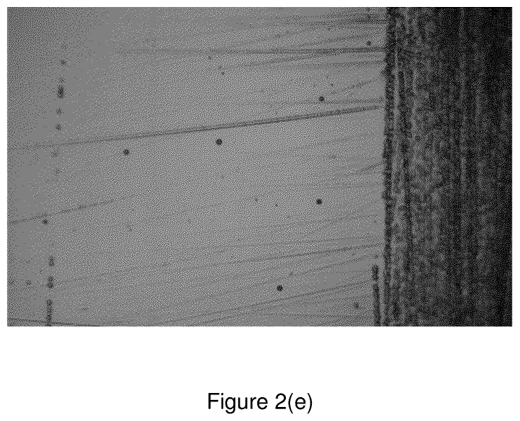

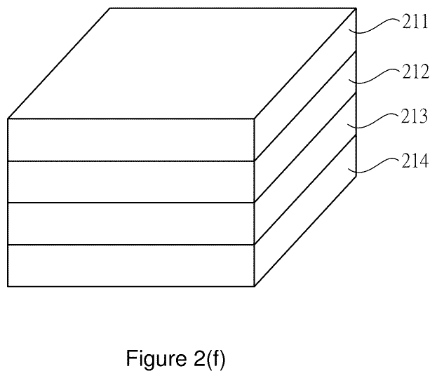

At this stage, as illustrated in FIG. 2(a), after appropriate cutting, a silicon wafer (or silicon carbide wafer) 202 of the same surface area is selected to affix on the test wafer as a protective wafer. The single-crystal silicon carbide test wafer 201B intends to perform tapered grinding and polishing, which is affixed to a wedge-shaped metal mold 201, specifically on the inclined plane 201A. The single-crystal silicon carbide test wafer is then ground using ascending grit sandpaper in sequence, followed by a polishing process.

As shown in Step 104 of FIG. 1A, a chemical etching process is performed by using a molten inorganic alkali and a molten carbonate as a mixture solution. The temperature of the chemical etching process is controlled between 380° C. and 450° C., and the time duration of the chemical etching process is set between 1 minute and 20 minutes to reveal the brittle characteristics of the single-crystal silicon carbide test wafer. The molar ratio of carbonate to inorganic alkali is between 0 and 10 mol. %. The inorganic alkali includes lithium hydroxide (LiOH), sodium hydroxide (NaOH), potassium hydroxide (KOH), barium hydroxide (Ba(OH)₂), and calcium hydroxide (Ca(OH)₂). The carbonate includes lithium carbonate (Li₂CO₃), sodium carbonate (Na₂CO₃), potassium carbonate (K₂CO₃), magnesium carbonate (MgCO₃), and calcium carbonate (CaCO₃).

As shown in Step 105 of FIG. 1A, after the chemical etching process, the single-crystal silicon carbide test wafer will be taken to rinse with deionized water. The inclined plane of the single-crystal silicon carbide test wafer is then examined by using an optical microscope, also the length (L1) of microcrack is measured.

FIG. 2(b) illustrates a schematic diagram of microcracks (L1) or dislocations formed after the polishing and etching process. This diagram includes non-tapered polished region 220, interface 221, tapered polished region 222, microcracks 223, dislocations 224, the “damage layer” thickness L1, and plastic deformation layer thickness L2.

As shown in FIG. 2(c), an optical microscope image of the single-crystal silicon carbide test wafer taken before the chemical etching process is presented, depicting the brittle characteristics.

Furthermore, as shown in FIG. 2(d), an optical microscope image presents the brittle characteristics of the single-crystal silicon carbide test wafer after the chemical etching process. The image highlights the presence of microcracks with the length (L1) on the inclined plane.

FIG. 1B illustrates a method for inspecting a silicon carbide wafer according to the present invention, which corresponds to the second embodiment of the invention. In this embodiment, a single-crystal silicon carbide wafer with an area ranging from 100 mm² to 400 mm² is selected as the test wafer.

As shown in Step 111 of FIG. 1B, the single-crystal silicon carbide test wafer undergoes heat treatment process in a high-temperature furnace. The heat treatment process is conducted at a temperature ranging from 800° C. to 2,200° C., within a duration of 0.1 hour to 3.0 hours, resulting in a heat-treated test wafer.

As shown in Step 112 of FIG. 1B, a standard ductility condition is established for residual plastic deformation analysis under high-temperature for subsequent inspection procedures. This standard helps to distinguish the elastic deformation layer in the single-crystal silicon carbide test wafer, when the excessive internal stress presenting. If the heat treatment process exceeds the ductile-to-brittle transition temperature (DBTT) of the silicon carbide, and the internal stress is higher than the critical yield strength, the stress will be released through dislocation multiplication and slip deformation. After the heat treatment process, the wafer is examined at room temperature, wherein the observed dislocations indicate the presence of plastic deformation induced by internal stress at high temperature. Therefore, at room temperature, the characteristic feature of the high-stress elastic deformation layer is the presence of dislocations.

As shown in Step 113 of FIG. 1B, the test silicon carbide single-crystal wafer is affixed to the inclined plane of a wedge-shaped metal mold by using wax-coating method, wherein the inclination angle range is between 1° and 20°. Then again, a silicon wafer or another silicon carbide wafer with the same area is affixed to the test wafer by the same method to protect the test wafer.

At this stage, as illustrated in FIG. 2(a), after appropriate cutting, a silicon wafer (or silicon carbide wafer) 202 with the same area is selected as a protective wafer. The test wafer 201B is designated for tapered grinding and polishing, which is attached to a wedge-shaped metal mold 201, specifically on the inclined plane 201A of the wedge-shaped metal mold. The test wafer is then sequentially ground using sandpaper with ascending grit size, followed by a polishing process.

As shown in Step 114 of FIG. 1B, a chemical etching process is performed by using a molten inorganic alkali liquid. The temperature of the chemical etching process is controlled between 420° C. and 530° C., with a time duration of the chemical etching process ranging from 1 minute to 30 minutes. This chemical etching process is designed to reveal the elastic deformation layer in the single-crystal silicon carbide wafer, where excessive stress exists under ductility conditions. The inorganic alkali includes lithium hydroxide (LiOH), sodium hydroxide (NaOH), potassium hydroxide (KOH), barium hydroxide (Ba(OH)₂), and calcium hydroxide (Ca(OH)₂).

As shown in Step 115 of FIG. 1B, after the chemical etching process, the silicon carbide single-crystal test wafer is taken to rinse with deionized water. The inclined plane of the silicon carbide single-crystal test wafer is then examined using an optical microscope. As illustrated in FIG. 2(b), the distance (L2) between the dislocation etching pits and the grinding or polishing interface is measured.

As illustrated in FIG. 2(e), an optical microscope image of the single-crystal silicon carbide wafer is shown after the heat treatment process above the ductile-to-brittle transition temperature (DBTT) and subsequent the chemical etching at room temperature.

FIG. 2(e) specifically illustrates the distance (L2) between the dislocation etching pits and the polishing interface after chemical etching, representing the total thickness of the damage layer and the high-stress elastic deformation layer. The dislocations appear as a continuous pattern along specific crystalline planes, and the distance (L2) is defined accordingly.

As further illustrated in Step 105 of FIG. 1A, and Step 115 of FIG. 1B, the thicknesses of the damage layer and high-stress elastic deformation layer of the single-crystal silicon carbide test wafer are calculated using L1 and L2 as follows:
Damage layer thickness=L1×sin (θ)
Total thickness of the damage layer and the high-stress elastic deformation layer=L2×sin (θ)
The thickness of the high-stress elastic deformation layer can be calculated by L1×sin (θ) subtracted from L2×sin (θ). Here, θ is the inclination angle of the wedge-shaped metal tapered surface to the horizontal plane (as shown in FIG. 2(a)).

Therefore, the damage layer thickness is calculated by using L1×sin (θ), wherein θ is the inclination angle of the wedge-shaped metal tapered surface with respect to the horizontal plane.

Additionally, the thickness of the residual plastic deformation layer under the high-temperature ductility condition is calculated using L2×sin (θ), wherein θ is the inclination angle of the wedge-shaped metal tapered surface with respect to the horizontal plane.

In other words, the thickness of the residual plastic deformation layer under the high-temperature ductility condition is calculated by using L2, and by subtracting this value from the total thickness of the single-crystal silicon carbide wafer, the thickness of the undamaged layer is determined.

FIG. 2(f) illustrates the vertical structure of the single-crystal silicon carbide wafer, including:
shattered/amorphous region 211,
damage layer 212,
high-stress elastic deformation layer 213, and
undamage layer 214,
which provides the material information of the vertical plane.

The shattered/amorphous region 211 is almost entirely removed during the initial processing, leaving a negligible thickness of less than 1 nm.

Therefore, thickness of the undamage layer can be determined by subtracting the total thickness of the damage layer and the high-stress elastic deformation layer from the known thickness of the single-crystal silicon carbide wafer.

In conclusion, the present invention offers several advantages as follows:
A. To determinate the thickness of each layer structure in the silicon carbide wafer precisely, including the damage layer, the high-stress elastic deformation layer, and the undamage layer.
B. To improve the reliability of the silicon carbide wafer for subsequent applications. Whether the wafer is used as a seed wafer or further device fabrication, the damage layer and the corresponding high-stress elastic deformation layer can be completely removed in the early stage, results in a low defect density and a high-quality wafer.
C. A low defect density and high-quality wafer can significantly enhance the yield to the crystal growth process and the device fabrication.

It will be appreciated that various modifications and adaptation may be made by those skilled in the art without departing from the scope and spirit of this invention. Accordingly, the scope of the appended claims is not limited to the specific embodiments describe herein but, shall be construed to encompass all the features of patentable novelty inherent in the present invention, including all equivalents that would be recognized by those skilled in the art to witch this invention pertains.

What is claimed is:

1. A method for inspecting a silicon carbide wafer, comprising:
providing a single-crystal silicon carbide test wafer at a room temperature;
establishing a brittleness characteristic analysis standard and performing a test;
affixing said single-crystal silicon carbide test wafer to an inclined plane of a wedge-shaped metal mold by using a wax-coating method;
performing a chemical etching process by using a molten inorganic alkali solution and a carbonate solution; and
retrieving said single-crystal silicon carbide test wafer and measuring a length L1 of a plurality of microcracks on said inclined plane of said wedge-shaped metal mold after said chemical etching process

2. The method of claim 1, wherein a molar ratio of carbonate to inorganic alkali comprises ranging from 0 to 10 mol. %.

3. The method of claim 1, wherein a temperature of said chemical etching process comprises controlled between 380° C. and 450° C., and a time duration of said chemical etching process comprising between 1 minute and 20 minutes.

4. The method of claim 2, wherein the inorganic alkali is selected from a group consisting of lithium hydroxide (LiOH), sodium hydroxide (NaOH), potassium hydroxide (KOH), barium hydroxide (Ba(OH)₂), and calcium hydroxide (Ca(OH)₂).

5. The method of claim 1, wherein the carbonate is selected from a group consisting of lithium carbonate (Li₂CO₃), sodium carbonate (Na₂CO₃), potassium carbonate (K₂CO₃), magnesium carbonate (MgCO₃), and calcium carbonate (CaCO₃).

6. The method of claim 1, wherein a thickness of a damaged layer of said silicon carbide wafer comprising calculated as L1×sin (θ), wherein θ is an inclination angle of a wedge-shaped metal tapered surface to a horizontal plane.

7. A method for inspecting a silicon carbide wafer, comprising:
performing a heat treatment process on a test single-crystal silicon carbide wafer in a high-temperature furnace;
establishing a residual plastic deformation analysis standard under high-temperature ductility conditions, following by a test;
attaching said single-crystal silicon carbide test wafer to an inclined surface of a wedge-shaped metal mold by using a wax-coating method;
preparing a molten inorganic alkali liquid and performing a chemical etching process; and
retrieving said single-crystal silicon carbide test wafer and measuring a distance L2 between a plurality of dislocation etching pits on said inclined plane of said wedge-shaped metal mold and a polishing interface of said single crystal silicon carbide test wafer after said chemical etching process.

8. The method of claim 7, wherein a temperature of said heat treatment process comprises ranging from 800° C. to 2,200° C., and a time duration of said heat treatment ranging from 0.1 hours to 3.0 hours.

9. The method of claim 7, wherein a temperature of said chemical etching process comprises controlled between 420° C. and 530° C., and a time duration of said chemical etching process being between 1 minute and 30 minutes.

10. The method of claim 7, wherein said inorganic alkali is selected from a group consisting of lithium hydroxide (LiOH), sodium hydroxide (NaOH), potassium hydroxide (KOH), barium hydroxide (Ba(OH)₂), and calcium hydroxide (Ca(OH)₂).

11. The method of claim 7, wherein a thickness of a residual plastic deformation layer under a high-temperature ductility condition of said silicon carbide wafer comprises calculated as L2×sin (θ), wherein θ is the inclination angle of a wedge-shaped metal tapered plane to a horizontal plane.

12. The method of claim 7, wherein a thickness of an undamage layer comprises calculated by subtracting a thickness of a residual plastic deformation layer under a high-temperature ductility condition from a total thickness of said single-crystal silicon carbide wafer.
